(19) United States
(12) Patent Application Publication
(10) Pub. No.: US 2024/0030883 A1
(43) Pub. Date: Jan. 25, 2024

(54) PROCESS FOR MANUFACTURING A PIEZOELECTRIC STRUCTURE FOR A RADIOFREQUENCY DEVICE AND WHICH CAN BE USED TO TRANSFER A PIEZOELECTRIC LAYER, AND PROCESS FOR TRANSFERRING SUCH A PIEZOELECTRIC LAYER

(71) Applicant: Soitec, Bernin (FR)

(72) Inventors: Arnaud Castex, Grenoble (FR); Laurence Doutre-Roussel, Fontanil Cornillon (FR); Eric Butaud, Grenoble (FR); Brice Tavel, Grenoble (FR)

(21) Appl. No.: 17/907,247

(22) PCT Filed: Mar. 24, 2021
(86) PCT No.: PCT/EP2021/057620

§ 371 Date: Mar. 17, 2023

(30) Foreign Application Priority Data
Mar. 24, 2020 (FR) FR2002834

(51) Int. Cl. H03H 3/08; H10N 30/073; H10N 30/082; H10N 30/086

(52) U.S. Cl. CPC H03H 3/08; H10N 30/073; H10N 30/082; H10N 30/086

(57) ABSTRACT

A method of manufacturing a piezoelectric structure comprises providing a substrate of piezoelectric material, providing a carrier substrate, depositing a dielectric bonding layer at a temperature lower than or equal to 300° C. on a single side of the substrate of piezoelectric material, a step of joining the substrate of piezoelectric material to the carrier substrate via the dielectric bonding layer, a thinning step for forming the piezoelectric structure, which comprises a layer of piezoelectric material joined to a carrier substrate.

### CROSS-REFERENCE TO RELATED APPLICATIONS

This application is a national phase entry under 35 U.S.C. § 371 of International Patent Application PCT/EP2021/057620, filed Mar. 24, 2021, designating the United States of America and published as International Patent Publication WO 2021/191303 A1 on Sep. 30, 2021, which claims the benefit under Article 8 of the Patent Cooperation Treaty to French Patent Application Serial No. FR2002834, filed Mar. 24, 2020.

### TECHNICAL FIELD

The present disclosure relates to a process for manufacturing a piezoelectric structure for a radiofrequency device that can be used to transfer a piezoelectric layer, and a process for transferring such a piezoelectric layer.

### BACKGROUND

It is known practice to manufacture a radiofrequency (RF) device, such as a resonator or filter, on a substrate comprising, successively, from its base to its surface, a carrier substrate, generally made of a material such as silicon or sapphire, an intermediate bonding layer and a piezoelectric layer.

Surface acoustic wave (SAW) filters typically comprise a piezoelectric layer and two electrodes in the form of two interdigitated metal combs deposited on the surface of the piezoelectric layer. Depending on the operation of the SAW filter, the thickness of the piezoelectric layer may be of the order of a few tens of nanometers up to several tens of μm. For the latter, there are parasitic modes of propagation that extend into the thickness of the piezoelectric layer and are liable to be reflected at the interface with the carrier substrate beneath. This phenomenon is called “rattle.” To avoid these parasitic modes, it is known practice to make the surface of the piezoelectric layer located at the interface with the intermediate bonding layer rough enough to allow the parasitic waves to be reflected in all directions. Given the contemplated operating wavelength of the resonator, the roughness of the rough surface of the piezoelectric layer is very high, of the order of the same magnitude as the operating wavelength (a few μm).

The piezoelectric layer is typically obtained by transferring a thick substrate of a piezoelectric material (for example, obtained by slicing an ingot) to a carrier substrate. The carrier substrate is, for example, a silicon substrate.

The transfer of the piezoelectric layer entails bonding the thick piezoelectric substrate to the carrier substrate, followed by thinning the thick piezoelectric substrate so as to leave only a thin piezoelectric layer on the carrier substrate, of the desired thickness for manufacturing the RF device.

To obtain good adhesion of the piezoelectric substrate to the carrier substrate, a layer of oxide (for example, a silicon oxide SiO₂) is generally deposited on each of the two substrates, and the substrates are bonded by way of the oxide layers.

On the one hand, since the piezoelectric material and the material of the carrier substrate have very different coefficients of thermal expansion, implementing such an anneal causes the assembly to deform substantially.

On the other hand, depositing an oxide layer on the thick piezoelectric substrate causes the piezoelectric substrate to bow substantially, which is incompatible with the later steps of the process, which are designed for flat substrates.

Lastly, as mentioned above, the heterostructure cannot undergo the consolidating anneal because of the differences in coefficients of thermal expansion between the thick piezoelectric substrate and the handle substrate. However, in the absence of the consolidating anneal, the bonding energy of the oxide layers of the two substrates remains very low, such that the mechanical strength of the donor virtual substrate is insufficient. Consequently, a break at the bonding interface may occur during the step of thinning the thick piezoelectric substrate.

To ensure good adhesion between the thick piezoelectric substrate and the carrier substrate, in particular, when the thick piezoelectric substrate has a high level of roughness, the current process requires a large number of steps such as the deposition of multiple oxide layers followed by chemical mechanical polishing (CMP) of the oxide layers, the oxide layers deposited alternately on both faces of the thick piezoelectric substrate in order to avoid substantial bowing that makes bonding impossible.

### BRIEF SUMMARY

The present disclosure aims to overcome these limitations of the prior art by proposing a process for manufacturing a piezoelectric structure for a radiofrequency device, which can also be used to transfer a piezoelectric layer, and a process for transferring such a piezoelectric layer.

The present disclosure relates to a process for manufacturing a piezoelectric structure, the process being characterized in that it comprises providing a substrate of piezoelectric material, providing a carrier substrate, depositing a dielectric bonding layer at a temperature less than or equal to 300° C. on a single face of the substrate of piezoelectric material, a step of joining the substrate of piezoelectric material to the carrier substrate by way of the dielectric bonding layer, a thinning step to form the piezoelectric structure comprising a layer of piezoelectric material joined to a carrier substrate.

Thus, the low stress caused by depositing a dielectric bonding layer at low temperature as mentioned above, less than or equal to 300° C., makes it possible to ensure sufficient mechanical stability allowing thinning steps as described in the rest of the description and during the packaging steps used subsequently during the manufacture of components.

In some embodiments, the dielectric bonding layer comprises a layer of silicon oxide deposited on the substrate of piezoelectric material by plasma-assisted chemical vapor deposition.

In advantageous embodiments, the joining step comprises a molecular bonding between the dielectric bonding layer and the carrier substrate or between the dielectric bonding layer and a dielectric bonding layer formed on the carrier substrate.

In advantageous embodiments, there is a bonding interface consolidation anneal at a temperature below the deposition temperature of the dielectric bonding layer.

In advantageous embodiments, the thinning step is performed at a temperature below the deposition temperature of the dielectric bonding layer.

In advantageous embodiments, the substrate of piezoelectric material has a rough surface designed to reflect a radiofrequency wave.

In advantageous embodiments, the thickness of the dielectric bonding layer is between 200 nm and 500 nm.

In advantageous embodiments, a dielectric bonding layer is provided on the carrier substrate.

In advantageous embodiments, the thinning step comprises etching and/or chemical mechanical polishing.

The present disclosure also relates to a process for transferring a piezoelectric layer to a final substrate, comprising providing a piezoelectric structure obtained by implementing the manufacturing process as claimed in any one of the preceding claims, forming a weakened zone in the layer of piezoelectric material so as to delimit the piezoelectric layer to be transferred, providing the final substrate, preferably forming dielectric bonding layers on a main face of the final substrate and/or the layer of piezoelectric material, bonding the layer of piezoelectric material to the final substrate, breaking and separating the piezoelectric structure along the weakened zone, at a temperature less than or equal to the deposition temperature of the dielectric bonding layer.

In advantageous embodiments, the weakened zone is formed by implanting atomic species in the layer of piezoelectric material.

In advantageous embodiments, the final substrate and the carrier substrate have identical coefficients of expansion.

### BRIEF DESCRIPTION OF THE DRAWINGS

Other features and advantages of the present disclosure will be better understood from reading the detailed description that follows, with reference to the appended drawings, in which:

FIG. 1 shows a manufacturing process according to one embodiment of the present disclosure and a substrate according to this embodiment of the present disclosure;

FIG. 2 shows a manufacturing process according to another embodiment of the present disclosure and a substrate according to this other embodiment of the present disclosure;

FIG. 3 shows a transfer process according to one embodiment of the present disclosure; and

FIG. 4 shows a transfer process according to another embodiment of the present disclosure.

To improve the readability of the figures, the various layers are not necessarily shown to scale.

### DETAILED DESCRIPTION

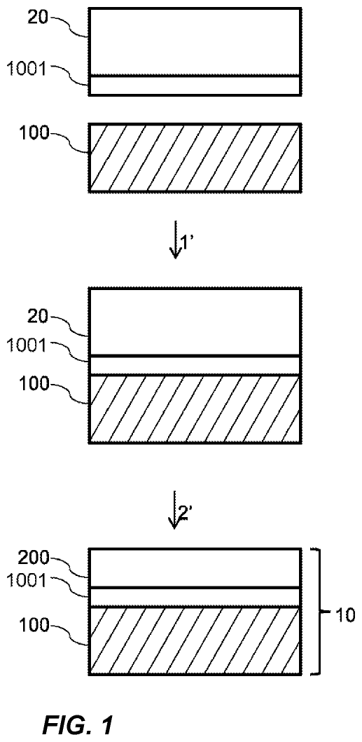

FIG. 1 shows a carrier substrate 100, preferably of silicon material, to which is transferred a layer of piezoelectric material 200, preferably of monocrystalline piezoelectric material, even more particularly of lithium tantalate or lithium niobate material. Other materials for the layer of piezoelectric material 200 may be envisaged. The active layer 200 to be transferred may also comprise a ferroelectric material, for example, LiTaO₃, LiNbO₃, LiAlO₃, BaTiO₃, PbZrTiO₃, KNbO₃, BaZrO₃, CaTiO₃, PbTiO₃ or KTaO₃.

The donor substrate comprising this active layer may take the form of a circular wafer of standardized size, for example, 150 mm or 200 mm in diameter. However, the present disclosure is not in any way limited to these dimensions or to this form. The donor substrate may have been taken from an ingot of ferroelectric materials in such a way that the donor substrate has a predetermined crystal orientation, or the donor substrate may comprise a layer of ferroelectric material joined to a carrier substrate. The crystal orientation of the active layer of ferroelectric material to be transferred is chosen according to the intended application. Thus, as regards the material LiTaO₃, it is customary to choose an orientation of between 30° and 60° XY, or between 40° and 50° XY, in particular, when wanting to make use of the properties of the thin layer to form a SAW filter. As regards the material LiNbO₃, it is customary to choose an orientation of about 128° XY. However, the present disclosure is by no means limited to a particular crystal orientation.

Whatever the crystal orientation of the ferroelectric material of the donor substrate, the process comprises, for example, introducing hydrogen and/or helium species (ions and/or atoms) into this donor substrate. This introduction may correspond to, for example, a hydrogen implantation, that is to say a hydrogen ion bombardment of the planar face of the donor substrate. As is known per se, the aim of the implanted ions is to form a weakened plane delimiting a first layer of ferroelectric material to be transferred, which layer is located on the face side, and another section forming the rest of the substrate. The nature, the dose of the implanted species and the type of ions implanted, and the implantation energy, are chosen depending on the thickness of the layer that it is desired to transfer and on the physicochemical properties of the donor substrate. In the case of a donor substrate made of LiTaO₃, it will thus be possible to choose to implant a dose of hydrogen of between 1×10¹⁶ and 5×10¹⁷ at/cm² with an energy of between 30 and 300 keV in order to define a first layer of about 10 to 2000 nm.

The carrier substrate 100 of silicon material may also be replaced by a carrier substrate 100 of sapphire material, polycrystalline aluminum nitride (AlN), glass, or any other material having a coefficient of thermal expansion below or opposite to the coefficient of thermal expansion of the piezoelectric material of the layer of piezoelectric material 200 (in the present disclosure it is the coefficient of thermal expansion in a plane parallel to the main surface of the substrates that is of interest). Thus, the carrier substrate 100 plays the role of a stiffener that limits the expansion of the piezoelectric structure 10 during temperature variations to which it is subjected, this making it possible to decrease the thermal frequency coefficient of the layer of piezoelectric material 200, that is to say the extent to which the frequency of a wave propagating through the layer of piezoelectric material 200 varies with temperature. Silicon is particularly preferred because it allows the addition of functionalities allowing electrical isolation for RF applications resulting from the addition of a surface trapping layer.

The use of silicon has the advantage of not only opening up the field of application of films of piezoelectric material for 300 mm-type large-scale equipment, but also making it compatible with the microelectronics industry, for which the requirements in terms of acceptance on the production line for exotic material other than silicon, in particular, lithium tantalate or lithium niobate, are high. It is thus also possible to envisage integrating components obtained or manufactured in the layer of ferroelectric or even piezoelectric material, such as SAW and/or BAW filters, with components obtained or formed in the silicon substrate, such as transistors, power amplifiers or even network switches, thus reducing the losses in the interconnections between different types of components and making such a system integrating multiple components more compact.

FIG. 1 schematically shows the joining step 1′ for joining a substrate of piezoelectric material 20 to the carrier substrate 100, preferably of silicon material. The joining step 1′ for joining the substrate of piezoelectric material 20 to the carrier substrate 100, preferably of silicon material, is preferably performed by means of a molecular adhesion step. This molecular adhesion step comprises a bonding step, preferably at room temperature, and may be followed by a consolidation anneal of the bonding interface.

The deposition of a dielectric bonding layer 1001 on a single face of the substrate of piezoelectric material 20, before the joining step 1′ for joining the substrate of piezoelectric material 20 to the carrier substrate 100 by way of this dielectric bonding layer 1001, is also shown schematically. This dielectric bonding layer 1001 is deposited at a temperature less than or equal to 300° C. In general, the deposition temperature of the dielectric bonding layer 1001 is chosen such that the bow caused by the difference in coefficient of thermal expansion between the substrate of piezoelectric material 20 and the dielectric bonding layer 1001 remains compatible with a molecular bonding step, the assembly composed of the substrate of piezoelectric material 20 and the dielectric bonding layer 1001 having bowing less than or equal to 100 μm. The thickness of the dielectric bonding layer 1001 should be considered. Over the envisaged thickness range varying between 200 nm and 500 nm, a deposition temperature less than or equal to 300° C. shows good results. It was found that not only does the bowing (80 to 90 μm for a 500 nm dielectric bonding layer 1001) remain below the threshold value compatible with a molecular bonding (around 100 μm), but also the nature of the dielectric bonding layer 1001 is such that the bonding energy obtained between the dielectric bonding layer 1001 and the carrier substrate 100 is improved. The bonding energies may thus reach high values greater than 1 J/m². These energies are high enough to allow a stable mechanical strength during subsequent steps such as the thinning step or a consolidation anneal step.

The molecular adhesion step is preferably carried out at room temperature, i.e., approximately 20° C. It is, however, possible to carry out this direct hot bonding at a temperature of between 20° C. and 50° C. In addition, the bonding step is advantageously carried out at low pressure, that is to say at a pressure less than or equal to 5 mTorr (1 Torr is exactly 101325/760 pascals, i.e., approximately 133.322 Pa), which allows desorption of the water from the surfaces forming the bonding interface. Carrying out the bonding step under vacuum allows the desorption of water at the bonding interface to be improved further still.

In an advantageous embodiment, the substrate of piezoelectric material 20 has a rough surface designed to reflect a radiofrequency wave. In the present text, “rough surface” means a surface whose roughness is of the same order of magnitude as the wavelength of the RF waves intended to propagate in the piezoelectric layer of the resonator or filter, so as to allow the reflection of parasitic waves in all directions so that they no longer contribute to the output signal of the resonator or filter in question. In the context of the present disclosure, the roughness of such a surface is between 1.0 and 1.8 μm measured peak-to-valley. To fill this roughness, the dielectric bonding layer 1001 has a thickness greater than the roughness; flatness is obtained by means of a chemical and/or mechanical etching step.

Preferably, the dielectric bonding layer 1001 comprises a layer of silicon oxide deposited on the substrate of piezoelectric material 20, preferably by plasma-assisted chemical vapor deposition.

According to another embodiment, the dielectric bonding layer 1001 is a layer of silicon oxide, or a layer of silicon nitride, or a layer comprising a combination of silicon nitride and oxide, or a superposition of at least one layer of silicon oxide and one layer of silicon nitride, preferably obtained by plasma-assisted chemical vapor deposition.

In an advantageous embodiment, a bonding interface consolidation anneal is carried out in order to reinforce the mechanical strength of the piezoelectric structure. This anneal is carried out at a temperature below the deposition temperature of the dielectric bonding layer 1001, and thus makes it possible to increase the bonding energy without, however, producing a defect at the bonding interface due to the presence of any impurities (such as hydrogen) and their degassing and migration toward this interface during such an anneal. The consolidation anneal is normally performed at temperatures less than or equal to 300° C., for a period varying from a few minutes to a few hours.

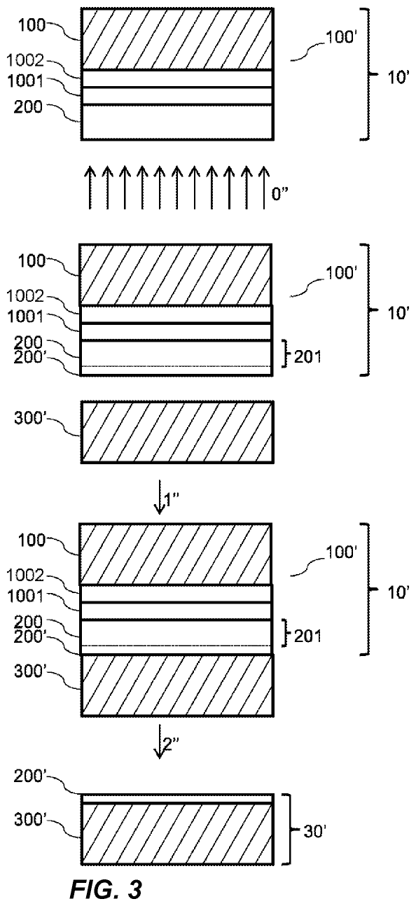

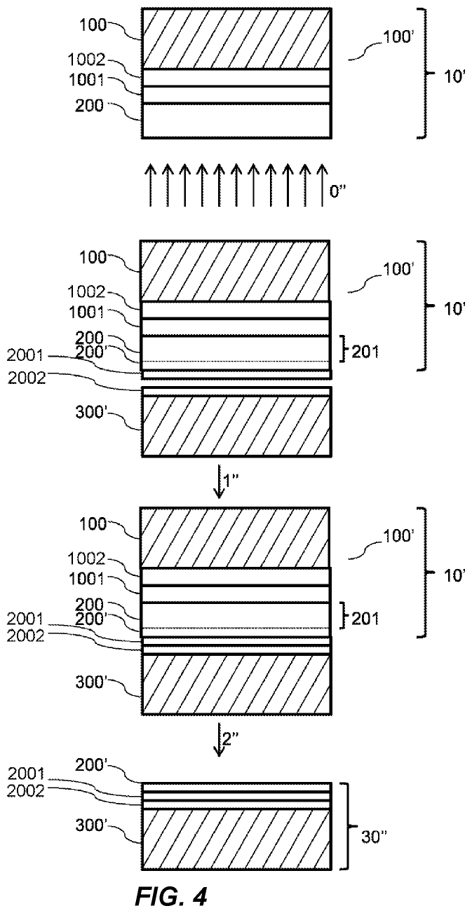

As shown schematically in FIG. 1, there follows a thinning step 2′ for thinning the substrate of piezoelectric material 20 after it has been joined to the carrier substrate 100. FIG. 1 schematically shows the thinning step 2′, which may be implemented, for example, by means of chemical and/or mechanical etching (polishing, grinding, milling, etc.). In this way, the layer of piezoelectric material 200 can be obtained. The thinning step may also involve application of the SMARTCUT™ method. This method is shown schematically in FIGS. 3 and 4 and involves forming a weakened zone in the layer to be transferred so as to delimit the layer to be transferred from the remaining layer of the substrate chosen for transfer, providing a receiving substrate to which the layer to be transferred is transferred, a step of joining the layer to be transferred to the receiving substrate, generally by means of molecular bonding, then a detachment step that comprises breaking and separating along the weakened zone, thus forming a heterostructure comprising the layer to be transferred to the receiving substrate. The thinning step is generally performed at a temperature below the deposition temperature of the dielectric bonding layer 1001, which makes it possible to avoid the presence of aforementioned defects at the bonding interface due to the presence of any impurities (such as hydrogen) and their degassing and migration toward this interface during such a thinning step.

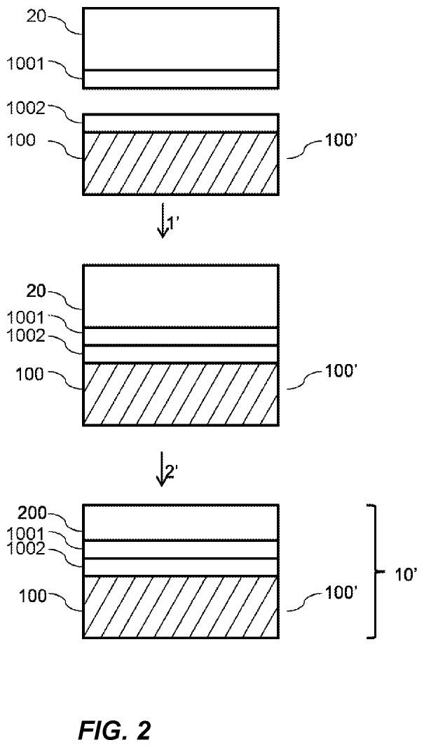

The manufacturing process shown schematically in FIG. 2 differs from the manufacturing process shown schematically in FIG. 1 in that, before the joining step 1′, a dielectric bonding layer 1002 is formed on the carrier substrate 100, which layer is thus present in the piezoelectric structure 10′ obtained by means of the manufacturing process according to the present disclosure. Depending on the material chosen for the carrier substrate 100, this dielectric bonding layer 1002 is formed in such a way as to allow a molecular bonding between the assembly composed of the substrate of piezoelectric material 20 and the dielectric bonding layer 1001 and the assembly 100′ composed of the carrier substrate 100 and the dielectric bonding layer 1002. The bowing of the assembly 200′ thus remains less than or equal to 100 p.m.

Preferably, the dielectric bonding layer 1002 comprises a layer of silicon oxide. In the case of a carrier substrate 100 made of silicon material, it may be a thermal oxide, but the present disclosure is not limited to this. In a non-limiting manner, it can also be obtained by plasma-assisted chemical vapor deposition.

FIG. 3 schematically shows an embodiment of a process for transferring a piezoelectric layer 200′ to a final substrate 300′, comprising providing a piezoelectric structure 10′ (obtained using the process shown schematically in FIG. 2 in the knowledge that the present disclosure is not limited to this embodiment), forming a weakened zone 0″ in the layer of piezoelectric material 200 so as to delimit the piezoelectric layer 200′ to be transferred from the remaining layer 201 of the layer of piezoelectric material 200, providing the final substrate 300′, a step of joining 1″ the layer of piezoelectric material 200 to the final substrate 300′, a detachment step 2″ that comprises breaking and separating the piezoelectric structure 10′ along the weakened zone, thus forming the heterostructure 30′ comprising the piezoelectric layer 200′ on the final substrate 300′. The detachment step is preferably performed at a temperature less than or equal to the deposition temperature of the dielectric bonding layer 1001, preferably at a temperature less than or equal to 300° C.

The transfer process shown schematically in FIG. 4 differs from the transfer process shown schematically in FIG. 3 in that, before the joining step 1″, a dielectric bonding layer 2001 is formed on the piezoelectric structure 10′ and a dielectric bonding layer 2002 is formed on the final substrate 300′; these two dielectric bonding layers 2001 and 2002 are thus present in the heterostructure 30″ obtained by means of the transfer process according to the present disclosure.

The thickness of the dielectric layer of the final structure is thus the sum of the thicknesses of the two dielectric bonding layers. When the thickness of the dielectric layer of the final structure needs to comply with a certain range of values, a certain flexibility in the manufacture of these layers is obtained either on the piezoelectric structure or on the final substrate. For example, the final substrate could already include components as mentioned above and thus would not be able to exceed a certain thermal budget so as not to damage these components. It is thus possible to form a greater thickness of dielectric layer on the piezoelectric structure than on the final substrate.

The present disclosure is not limited to this and there may only be formation of one of the dielectric bonding layers, either on the piezoelectric structure 10′ or on the final substrate 300′.

The joining step 1″ for joining the piezoelectric structure 10′ to the final substrate 300′, preferably of silicon material, is preferably performed by means of a molecular adhesion step. This molecular adhesion step comprises a bonding step, preferably at room temperature, and may be followed by a consolidation anneal of the bonding interface.

For the transfer processes shown schematically in FIGS. 3 and 4, the weakened zone 0″ is formed by implanting atomic species in the layer of piezoelectric material 200. In general, the implantation step 0″ is performed using hydrogen ions. One interesting alternative well known to those skilled in the art involves replacing all or some of the hydrogen ions with helium ions.

For a layer of piezoelectric material 200 of lithium tantalate, a hydrogen implantation dose will typically be between 6×10¹⁶ cm⁻² and 1×10¹⁷ cm⁻². The implantation energy will typically be between 50 and 170 keV. Thus, the detaching is typically performed at temperatures of between 150° C. and 300° C. Thicknesses of the piezoelectric layer 200′ of the order of 10 nm to 500 nm are thus obtained.

The final substrate 300′ and the carrier substrate 100 may advantageously have an identical, or at least very close, coefficient of thermal expansion, which allows better mechanical strength and less deformation during bonding interface consolidation annealing. The two substrates may be of identical nature, substantially made of silicon apart from the dielectric bonding layers or a trapping layer that is possibly present. The latter do not have a sufficient thickness to significantly influence the benefit of the “sandwich” structure having a final substrate 300′ and a carrier substrate 100 of the same material.

Just after the detachment operation, additional technological steps are advantageously added with the aim of either strengthening the bonding interface, or restoring a good level of roughness, or correcting any defects generated during the implantation step (or else to prepare the surface for the resumption of other process steps such as the formation of electrodes for the SAW-type device, for example). These steps are, for example, polishing, chemical etching (wet or dry), annealing, chemical cleaning. They may be used alone or in combination, which those skilled in the art will be capable of adjusting.

In advantageous embodiments, the carrier substrate 100 and/or the final substrate 300′ may be a silicon substrate having an electrical resistivity greater than 1 k·ohm·cm. This carrier substrate 100 and/or final substrate 300′ may also include a charge trapping layer placed on the surface of this silicon substrate intended to be joined. The trapping layer may comprise undoped polysilicon. Under certain circumstances, and, in particular, when the trapping layer has a sufficient thickness, for example, greater than 30 μm, the silicon base substrate may have a standard resistivity, less than 1 k·ohm·cm. In general, it is a non-crystalline layer having structural defects such as dislocations, grain boundaries, amorphous zones, interstices, inclusions, pores, etc. These structural defects form traps for the charges liable to flow through the material, for example, at the site of incomplete or dangling chemical bonds. Conduction is thus prevented in the trapping layer, which consequently exhibits high resistivity. Advantageously, and for reasons of simplicity of implementation, this trapping layer is formed by a layer of polysilicon. Its thickness, in particular, when it is formed on an electrically resistive silicon base substrate, may be between 0.3 μm and 3 μm. But other thicknesses below or above this range are quite possible, depending on the expected level of RF performance. In order to seek to preserve the polycrystalline quality of this layer during the heat treatments that the carrier substrate 100 or the final substrate 300′ may undergo, an amorphous layer can advantageously be provided, made of silicon dioxide, for example, on this substrate before the deposition of the charge trapping layer. Alternatively, the trapping layer can be formed by implanting a heavy species, such as argon, in a surface thickness of the substrate, in order to form therein the structural defects constituting the electrical traps. This layer can also be formed by porosifying a surface thickness of the substrate.

1. A method of manufacturing a piezoelectric structure for a radiofrequency device, comprising:
providing a substrate of piezoelectric material;
providing a carrier substrate;
depositing a dielectric bonding layer at a temperature less than or equal to 300° C. on a single face of the substrate of piezoelectric material;
a step of joining the substrate of piezoelectric material to the carrier substrate by way of the dielectric bonding layer; and
a thinning step to form the piezoelectric structure comprising a layer of piezoelectric material joined to a carrier substrate.

2. The method of claim 1, wherein the dielectric bonding layer comprises a layer of silicon oxide deposited on the substrate of piezoelectric material by plasma-assisted chemical vapor deposition.

3. The method of claim 2, wherein the joining step comprises a molecular bonding between the dielectric bonding layer and the carrier substrate or between the dielectric bonding layer and a dielectric bonding layer formed on the carrier substrate.

4. The method of claim 3, further comprising a bonding interface consolidation anneal at a temperature below the deposition temperature of the dielectric bonding layer.

5. The method of claim 4, wherein the thinning step is performed at a temperature below the deposition temperature of the dielectric bonding layer.

6. The method of claim 5, wherein the substrate of piezoelectric material has a rough surface configured to reflect a radiofrequency wave.

7. The method of claim 6, wherein the thickness of the dielectric bonding layer is between 200 nm and 500 nm.

8. The method of claim 7, further comprising providing a dielectric bonding layer on the carrier substrate.

9. The method of claim 8, wherein the thinning step comprises etching and/or chemical mechanical polishing.

10. A method of transferring a piezoelectric layer to a final substrate, comprising:
providing a piezoelectric structure obtained by implementing the method of claim 1;
forming a weakened zone in the layer of piezoelectric material so as to delimit the piezoelectric layer to be transferred; providing the final substrate,
a step of bonding together the layer of piezoelectric material and the final substrate; and
a detachment step comprising breaking and separating the piezoelectric structure along the weakened zone, at a temperature less than or equal to the deposition temperature of the dielectric bonding layer.

11. The method of claim 10, wherein the weakened zone is formed by implanting atomic species in the layer of piezoelectric material.

12. The method of claim 10, wherein the final substrate and the carrier substrate have identical coefficients of expansion.

13. The method of claim 10, further comprising forming a dielectric bonding layer on a main face of the final substrate and/or on the layer of piezoelectric material prior to the bonding step.

14. The method of claim 1, wherein the joining step comprises a molecular bonding between the dielectric bonding layer and the carrier substrate or between the dielectric bonding layer and a dielectric bonding layer formed on the carrier substrate.

15. The method of claim 1, further comprising a bonding interface consolidation anneal at a temperature below the deposition temperature of the dielectric bonding layer.

16. The method of claim 1, wherein the thinning step is performed at a temperature below the deposition temperature of the dielectric bonding layer.

17. The method of claim 1, wherein the substrate of piezoelectric material has a rough surface configured to reflect a radiofrequency wave.

18. The method of claim 1, wherein the thickness of the dielectric bonding layer is between 200 nm and 500 nm.

19. The method of claim 1, further comprising providing a dielectric bonding layer on the carrier substrate.

20. The method of claim 1, wherein the thinning step comprises etching and/or chemical mechanical polishing.
